(19) United States
(12) Patent Application Publication
(10) Pub. No.: US 2006/0250049 A1
(43) Pub. Date: Nov. 9, 2006

(54) Surface acoustic wave device package

(75) Inventors: Doo Cheol Park, Suwon (KR); Young Jin Lee, Yongin (KR); Seung Hee Lee, Suwon (KR); Joo Hun Park, Suwon (KR); Sang Wook Park, Suwon (KR); Nam Hyeong Kim, Suwon (KR)

Correspondence Address: LOWE HAUPTMAN BERNER, LLP, 1700 DIAGONAL ROAD, SUITE 300, ALEXANDRIA, VA, 22314, US

(73) Assignee: Samsung Electro-Mechanics Co., Ltd., Suwon (KR)

(21) Appl. No.: 11/259,199

(22) Filed: Oct. 27, 2005

(30) Foreign Application Priority Data
May 4, 2005 (KR) 10-2005-37420

(51) Int. Cl. H01L 41/053

(52) U.S. Cl. 310/344

(57) ABSTRACT

The present invention provides a SAW device package used in filters, duplexers, etc., in particular, which simplifies sealing process for protecting the active area of a SAW device. The SAW device package comprises a wiring substrate, as a package base having connection patterns, having bare chip attaching means. A bare chip is flip-bonded and attached to the attaching means on the wiring substrate while maintaining the airtight condition. A resin molding part covers the top of the bare chip to seal the device. The invention facilitates maintaining an airtight condition of the active area which affects the operational characteristics of the device, and simplifies the manufacturing processes. Furthermore, the improved structure of the wiring substrate blocks the external moisture permeation, thereby enabling the device to better withstand the external changes.

### CLAIM OF PRIORITY

This application claims the benefit of Korean Patent Application No. 2005-37420 filed on May 4, 2005, in the Korean Intellectual Property Office, the disclosure of which is incorporated herein by reference.

### BACKGROUND OF THE INVENTION

1. Field of the Invention

The present invention relates to a Surface Acoustic Wave (SAW) device package used in filters, duplexers, etc. More particularly, the present invention relates to a SAW device package, in which instead of using a prior dam structure to block the resin permeation into an active area, the wiring substrate is structurally improved into a stair form and the SAW in a bare chip is flip-bonded thereon so as to secure an airtight space in the active area, thereby facilitating the formation of an airtight condition in the active area as well as simplifying the manufacturing processes. Furthermore, the improved structure of the wiring substrate blocks moisture permeation from outside as well as enabling the SAW device to better withstand the external changes overall.

2. Description of the Related Art

As the telecommunication industry has been advancing recently, the wireless telecommunication products are becoming more compact, high-quality, and multi-function. Therefore, the current trend of compact size and multi-function is also required in the devices used in the wireless telecommunication products, such as filters, duplexers, etc.

Examples of such devices include a SAW filter, etc. whose operating principles are illustrated in FIG. 1. As shown in FIG. 1, in a SAW device, when electric signals are applied through an input electrode 130a to two electrodes 120a and 120b, (also called Inter Digital Transducer (IDT) electrodes) formed in a comb shape, facing each other on a piezoelectric material 110, piezoelectric distortion caused by piezoelectric effect occurs in the degree equivalent to the length of which the piezoelectric electrodes 120a and 120b overlap each other. The above piezoelectric distortion, in turn, causes the occurrence of surface acoustic waves which are conveyed to the piezoelectric material 110, and converted into electric signals to be outputted through an output electrode 130b.

At this time, only the electric signals of set frequency broadband, determined by the factors such as widths, lengths of or distances between IDT electrodes 120a and 120b, are filtered.

Therefore, in a SAW device, since the characteristics of a device is determined by piezoelectric material 110, that is, widths, lengths of, or distances between the IDT electrodes 120a and 120b, the characteristics of a SAW device change if the IDT electrodes are damaged, or stained by any foreign material of minute size such as dirt or dust particles.

For example, if a SAW device is used for a filter, in order to provide frequency selectivity, it is adapted to form RF or IF filter device which is sensitively affected by the condition of the above-described area that distributes the surface acoustic waves along the piezoelectric surface or nearby (referred to as ‘active area’ hereinafter). Therefore, the SAW device should be packaged airtight to block the physical affects from outside, and it is ideal to maintain the active area of the SAW device in a vacuum, but at the least, it should be protected by an air gap with no dust, etc.

Therefore, in case of a SAW device, a packaging technique for protecting IDT electrodes 120a and 120b from the external environment is required, in which maintaining an airtight condition of the active area is essential.

On the other hand, compact size is an important factor in the development of SAW devices such as filters, duplexers, etc., and one of the packaging techniques that accommodates size reduction is Chip Size Package Type (CSP)

To be specific, as shown in detail in FIG. 2, in case of a SAW filter, a filter chip (bare chip) is disposed electrically connected to a package sheet (wiring substrate) through bumps, and then a protection layer is formed on top to block the external conditions from the active area

In other words, as shown in FIG. 2, in a prior SAW device package 200, a bare chip 230, manufactured in a chip size with IDT electrodes 232 and metal bumps 234, is flip-bonded to a wiring substrate, or a package sheet made of ceramic, etc., having connecting patterns 212 thereon. On the top of the bare chip 230, a resin molding part 250 is formed, with an airtight space to segregate the active area (A) of the IDT electrodes 232 from outside. Particularly, on the rim of the bare chip 230, a resin or metal dam structure 270 in a surrounding form is constructed to block resin permeation into the active area (A).

Therefore, in a prior SAW device package, while resin is molded to block the external conditions from the active area (A), a dam structure 270 is required to block the resin permeation from the resin molding part 250 to the active area (A) at the same time.

To be specific, having fluidity in a liquid form or in a high temperature, resin of the resin molding part 250 might permeate into the active area (A) during the resin molding process, and thus, a dam structure 270 is formed to block such resin permeation.

However, in a prior SAW device package 200 with a dam structure, it was not easy to construct a resin or metal dam structure 270 on the rim of the bare chip 230, in a surrounding form, in a certain thickness or greater, the manufacturing process was complicated, and the costs were high.

In other words, the resin permeation from the resin molding part 250 is effectively blocked only when the dam structure 270 provided in the prior SAW device package 200 is maintained thicker than the certain thickness, and is provided on the rim of the bare chip in a surrounding form without any gaps. Thus, in reality, forming the dam structure is not easy, requires complicated processes, and costs much.

In addition, as shown in FIG. 2, great precision is required in maintaining the height of such a dam structure because if the height of the dam structure is not maintained at a certain level, a sufficient intensity of adhesion may not be obtained between the bumps 234 of the bare chip 230 and the connecting patterns 212 on the wiring substrate 210.

In a prior SAW device package 200, although a dam structure 270 blocks the resin permeation from the resin molding part 250, maintaining an airtight condition in the active area (A) while blocking the external conditions, there have been problems in terms of manufacturing processes and costs in providing a package with a dam structure.

Therefore, it will be desirable to improve the structure of the wiring substrate to provide a contacting part which comes in contact with the bare chip, so as to prevent resin permeation from the resin molding part into the active area in simpler processes with lower costs.

### SUMMARY OF THE INVENTION

The present invention has been made to solve the foregoing problems of the prior art and it is therefore an object of the present invention to provide a SAW device package in which formation of an airtight condition in an active area affecting operational characteristics of a SAW device is facilitated, the manufacturing processes are simplified, and the cost-saving effect is expected from the improved processes.

It is another object of the present invention to provide a SAW device package in which the structure of a wiring substrate is improved to block the moisture permeation, thus maintaining the operational characteristics of the device regardless of the external changes, and enhancing the overall reliability of the device.

In order to realize the above objects, a SAW device package according to the present invention includes:

a wiring substrate, having bare chip attaching means, provided as a package base with connecting patterns thereon;

a bare chip attached to the bare chip attaching means while maintaining an airtight condition of an active area, and flip-bonded to the wiring substrate; and

a resin molding part covering and sealing the bare chip.

In this case, the bare chip may include a plurality of bumps which is formed on input/output terminals of IDT electrodes provided in the bare chip, and flip-bonded to the connecting patterns of the wiring substrate.

In addition, the bare chip attaching means may include a first protrusion part that protrudes integrally in a surrounding form on the wiring substrate in order for the rim of the bare chip to be tightly attached when the bare chip is flip-bonded.

Moreover, it is desirable that the SAW device package may further include a second protrusion part that protrudes on the rim of the first protrusion part i.e. the bare chip attaching means, allowing the resin molding part to seal a space between the bare chip and the second protrusion part.

At this time, the first protrusion part may protrude from the surface of the wiring substrate having the connecting patterns thereon, in a height corresponding to the thickness of the bumps bonded to the wiring substrate the second protrusion part protrudes from the first protrusion part in a height at least the same as the thickness of the bare chip. A resin molding part may be formed in a space between the second protrusion part and the sides of the bare chip to form resin molding.

It is desirable to provide the wiring substrate and the first protrusion part i.e. the bare chip attaching means, optionally together with the second protrusion part in a multi-layer ceramic structure by tape-casting.

In addition, it is desirable that the SAW device package may further include an adhesion layer that blocks the resin permeation from the resin molding part through the part where the bare chip is attached to the first protrusion part i.e. the bare chip attaching means.

The above adhesion layer may be made of metal of high ductility, or rubber.

Furthermore, it is desirable that the SAW device package may further include resin-receiving means on the first protrusion part i.e. the bare chip attaching means in order for resin to flow and be received before reaching the active layer in case of resin permeation from the resin molding part.

The above resin-receiving means may include a resin inflow groove formed from the surface to the inside of the first protrusion part.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a perspective view illustrating a SAW device (bare chip);

FIG. 2 is a structural view illustrating a SAW device package of the prior art having a dam structure to seal an active area;

FIG. 3 is a structural view illustrating a first embodiment of a SAW device package according to the present invention;

FIG. 4 is a structural view illustrating a second embodiment of a SAW device package according to the present invention;

FIG. 5 is a view of the principal part illustrating a wiring substrate and structures of a first protrusion part and a second protrusion part of FIG. 4;

FIG. 6 is a schematic view illustrating manufacturing steps of the SAW device package having the first and second protrusion parts of FIG. 4;

FIG. 7 is a structural view illustrating a variation to the SAW device package of FIG. 4; and

FIG. 8 illustrates another variation to the SAW device package of FIG. 4, in which

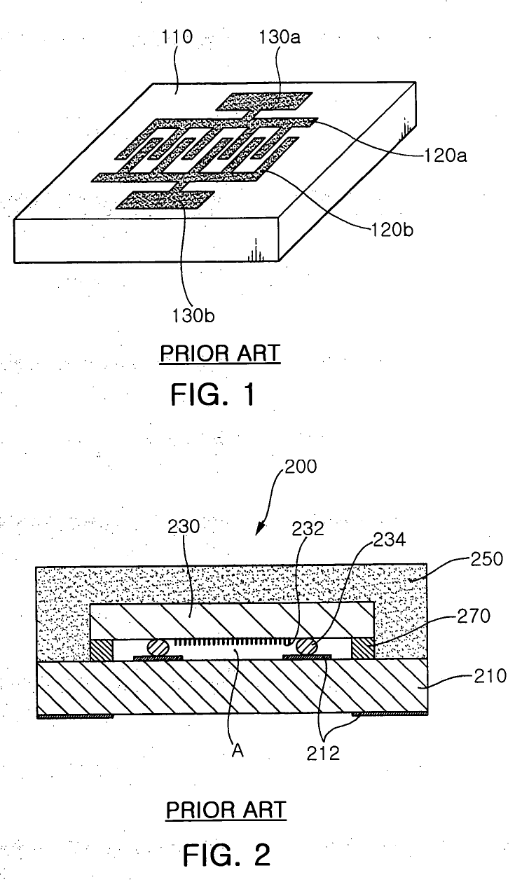

(a) is an overall structural view;

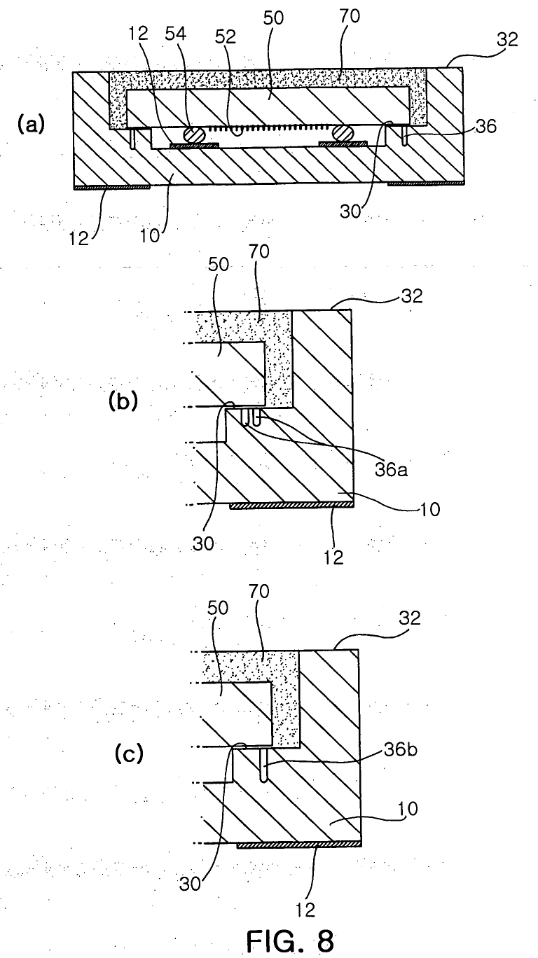

(b) is a view of the principal part illustrating a form of resin inflow groove of FIG. 8a; and

(c) is a view of the principal part illustrating an alternative form of resin inflow groove of FIG. 8a.

### DETAILED DESCRIPTION OF THE PREFERRED EMBODIMENT

Preferred embodiments of the present invention will now be described in detail with reference to the accompanying drawings.

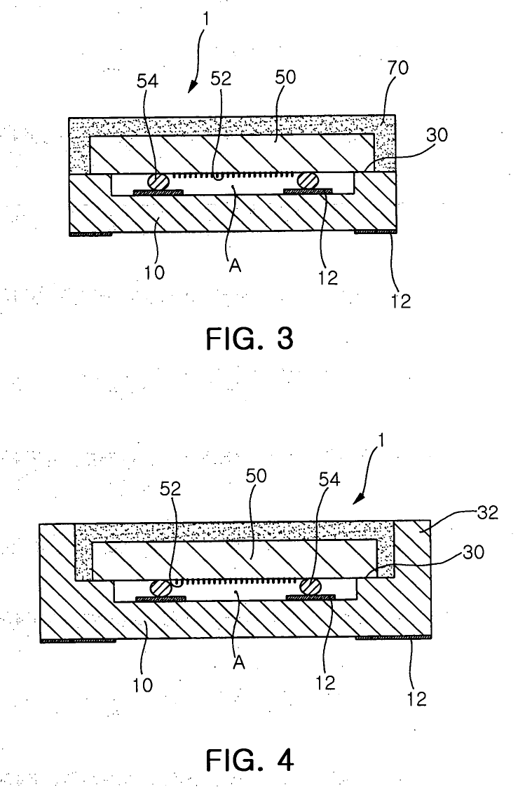

First, FIG. 3 illustrates a first embodiment of a SAW device package according to the present invention. As shown in FIG. 3, the SAW device package 1 according to the present invention includes a wiring substrate 10 having bare chip attaching means 30 and provided as a package base with connecting patterns 12 thereon a bare chip 50 attached to the above bare chip attaching means 30 while maintaining an airtight condition in an active area (A), and flip-bonded to the wiring substrate 10, and a resin molding part 70 covering the bare chip 50.

In the SAW device package of the first embodiment, instead of using a prior dam structure 270 to block the permeation into the active area (A) as in FIG. 2, the structure of the wiring substrate 10 is improved by forming the bare chip attaching means 30 on the wiring substrate 10 to allow tight attachment of the flip-bonded bare chip 50 to the wiring substrate 10, thereby achieving an excellent sealing quality in preventing resin permeation from the resin molding part 70 into the active area (A) which affects the operational characteristics of a device.

In this case, as shown in FIG. 3, flip-bonding of the bare chip 50 to the wiring substrate 10 is conducted by flip-bonding bumps 54 formed on input/output terminals (no numerals) of IDT electrodes 52 of the bare chip 50 to the connecting patterns 12 on the wiring substrate 10.

On the other hand, as shown in FIG. 3, the bare chip attaching means 30 on the wiring substrate 10 includes a first protrusion part protruding integrally in a surrounding form on the surface of the wiring substrate 10 in order for the rim of the bare chip 50 to be tightly attached to the bare chip attaching means 30.

In the present invention, the bare chip attaching means 30 of the first protrusion part protruding integrally on the wiring substrate 10, in fact protrudes integrally along a rim part of the wiring substrate 10 for seating the bare chip 50 thereon. Thus, the above-described rim of the bare chip 50 is tightly attached to the bare chip attaching means 30 of the first protrusion part when the bare chip 50 is flip-bonded.

Therefore, when the resin molding part 70 is formed over the bare chip 50, the resin permeation into the active area (A) can be prevented without the dam structure.

Next, FIG. 4 illustrates a second embodiment of a SAW device package according to the present invention. As shown in FIG. 4, a SAW device package 1 of the second embodiment further includes a second protrusion part 32 which protrudes on the rim of the first protrusion part i.e. the bare chip attaching means 30, in a surrounding form, allowing formation of a resin molding part 70 between the sides of the bare chip 50 and the second protrusion part to seal the device.

Therefore, the rim of the bare chip 50 is attached to the first protrusion part i.e. the bare chip attaching means 30 when flip-bonded, and the resin molding part 70 may be formed in the space between the attached bare chip 50 and the second protrusion part 32.

As a result, in the SAW device package 1 having the second protrusion part, as shown in FIG. 4, the bare chip 50 is tightly attached to the first protrusion part 30, forming an airtight condition, and flip-bonded to the wiring substrate 10. Moreover, as the resin molding part 70 is formed on the top of the bare chip 50, in the interior of the second protrusion part 32 which forms a wall, the sealing is more effective. Particularly, since the second protrusion part 32 is in a form that surrounds the resin molding part 70, moisture permeation from outside is further blocked against the active area (A).

Accordingly, in the SAW device package 1 of the second embodiment of the present invention, permeation of foreign materials, resin or moisture may be effectively blocked against the active area (A), thereby stabilizing the operational characteristics of the device, thereby enhancing the product reliability.

Moreover, in the SAW device packages according to the first and second embodiment of the present invention, as in FIG. 3 and FIG. 4, the wiring substrate 10 and the first protrusion part i.e. the bare chip attaching means 30 optionally together with the second protrusion part 32 are in fact provided in an integrally-formed ceramic structure.

In other words, according to the known tape-casting method, the first ceramic layer of the wiring substrate, the second ceramic layer of the first protrusion part, the third ceramic layer of the second protrusion part are made into desired tape forms respectively, and piled on one another in their order to provide an integrally-formed ceramic structure through plastic working.

On the other hand, in the first and second SAW device package of the present invention, the material of the resin molding part 70 formed over the attached bare chip 50 together with the first protrusion part, or in a space between the bare chip 50 and the second protrusion part 32, includes thermosetting films such as polyimide or epoxy films, or resin molding such as Epoxy Molding Compound, Epoxy Sheet Molding, Poly-Phenylene Oxide, a silicon film, etc.

At this time, it may be desirable to use highly viscous epoxy resin, which has great surface tension, so as to prevent the permeation through a fine gap at the contacting point of the bare chip 50 of the flip-bonded SAW device and the first protrusion part 30, into the active area (A).

Therefore, the above described SAW device package 1 of the second embodiment is the most ideal structure in which stable formation of the resin molding part 70 is allowed since the second protrusion part functioning as a wall increases the cohesiveness between the bare chip 50 and the wiring substrate 10. In particular, by functioning as a wall, the second protrusion part may enhance the overall structural stability of the package.

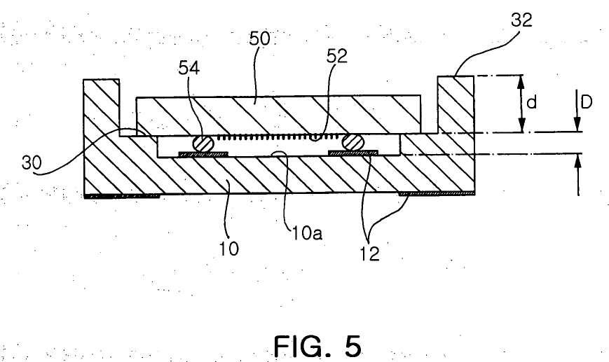

FIG. 5 illustrates an overall stair-form wiring substrate 10 having the first protrusion part i.e. the bare chip attaching means 30 and the second protrusion part 32. That is, as shown in FIG. 5, in the stair-form wiring substrate 10 made of ceramic, having connecting patterns 12 including upper and lower grounds, signal lines, etc., the distance from the inner floor surface 10a where bumps 54 are bonded when the bare chip is flip-bonded, to the first step of the first protrusion part 30 i.e. the bare chip attaching means 30 is a layer difference (D) that should be at least the same as the height of the bumps 54 after flip-bonding, for example, about 30 um.

In addition, the protrusion height (d) from the first protrusion part 30 to the second protrusion part 32 protruding from the outer edge of the first protrusion part, should be greater than the thickness of the attached bare chip, for example, about 250 um, so that subsequent forming of the resin molding part 70 completely wraps and seal the bare chip 50.

Moreover, as shown in FIG. 5, it is desirable that the first protrusion part is so formed that the attached area of the bare chip to the first protrusion part i.e. the bare chip attaching means 30 is not too narrow.

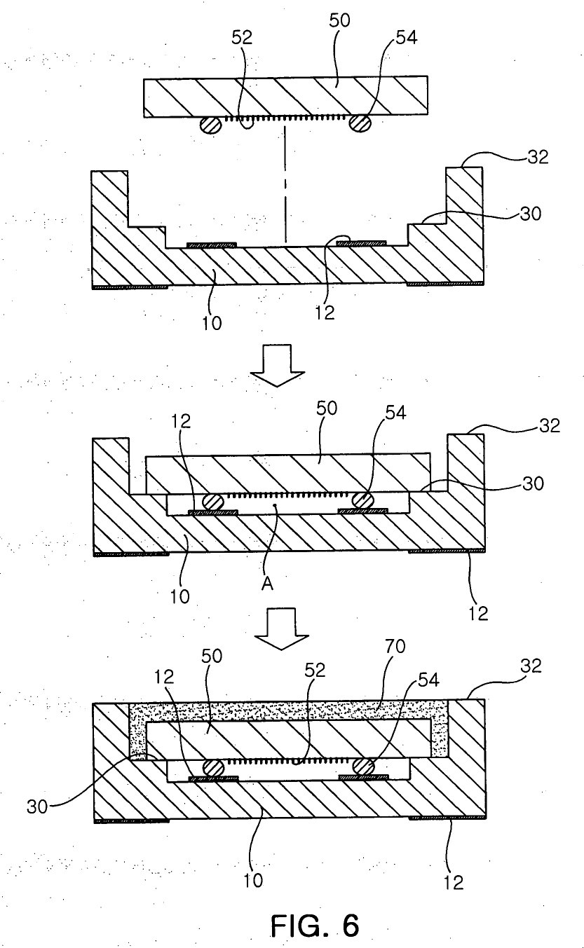

Next, FIG. 6 is a schematic view that illustrates the manufacturing process of the above described SAW device package of the second embodiment 1 of FIG. 4. First, in order to flip-bond the bare chip to the wiring substrate, stud bumps 54 of Au are applied on the surface of the bare chip 50 of the SAW device package, and flip-bonded to the connecting patterns 12 of the wiring substrate 10. The flip-bonding can be done by ultrasonic bonding or heat fusion bonding.

At this time, the wiring substrate 10 is not a product of plate formation, but as shown in FIG. 6, an integrally formed stair-form substrate including the first protrusion part i.e. the bare chip attaching means 30 and the second protrusion part 32.

Next, while the bare chip 50 is attached to the first protrusion part 30 maintaining an airtight condition in the active area (A), a resin molding part 70 is formed using a highly viscous epoxy resin such as EMC as described above.

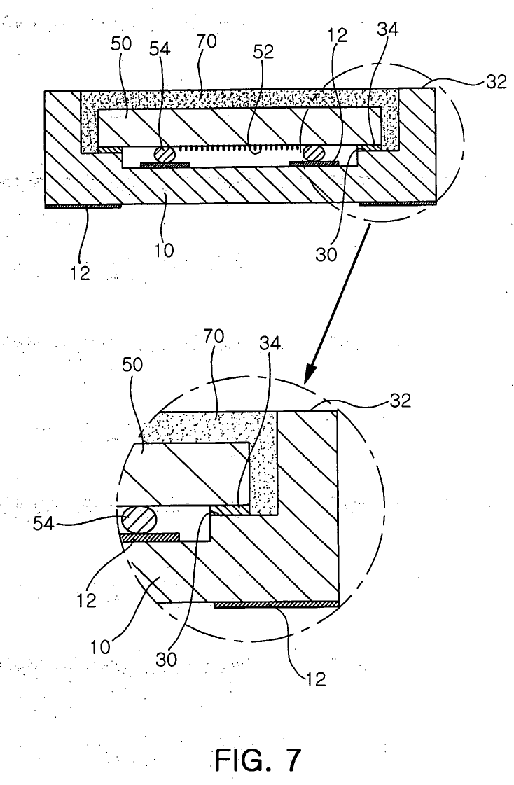

FIG. 7 illustrates a variation to the SAW device package illustrated in FIG. 4. As shown in FIG. 7, an adhesion layer 34 is provided to further prevent resin permeation from the resin molding part 70 through the part where the first protrusion part i.e. the bare chip attaching means 30 and the bare chip 50 are attached to each other.

Although a separate adhesion layer 34 may complicate the manufacturing process a bit, but since the adhesion layer is additionally provided between the bare chip and the first protrusion part i.e. the bare chip attaching means 30, the adhesion intensity of the bare chip 50 is increased, further blocking the resin permeation into the active area (A).

At this time, the above adhesion layer 34 is provided in a surrounding form along the contacting part of the bare chip and the wiring substrate. Thus, the adhesion layer 34 is thinner than the prior dam structure of FIG. 2, and in cooperation with the first protrusion part, prevents the resin permeation and increases the adhesion intensity of the bare chip.

In particular, it is desirable that the above adhesion layer 34 is made of metal of high ductility or rubber.

Next, FIG. 8 illustrates another variation to the SAW device package 1 of FIG. 4 In this variation, as shown in FIG. 8a, a resin-receiving means 36 is provided on the first protrusion part i.e. the bare chip attaching means 30, receiving the permeating resin from the resin molding part 70, thereby blocking the resin permeation into the active area (A).

Therefore, in case of resin permeation from the resin molding part 70 between the bare chip 50 and the first protrusion part 30 while the rim of the flip-bonded bare chip 50 is attached to the first protrusion part i.e. the bare chip attaching means 30, and the resin molding part 70 is formed between the second protrusion part and the bare chip 50, the resin is received at the resin-receiving means 36 to prevent permeation into the active area (A).

The above resin-receiving means 36, as shown in FIG. 8, may be provided with a plurality of grooves 36a that are not so deep or a single groove 36b that is quite deep.

Therefore, in the SAW device package of the present invention illustrated in FIG. 8, in case of resin permeation from the resin molding part 70 between the bare chip 50 and the first protrusion part 30 i.e. the bare chip attaching means 30, resin is received at the resin-receiving means 36, further preventing the permeation into the active area (A) which affects the SAW characteristics of the device.

According to the SAW device package of the present invention, the manufacturing processes will be simplified, the sealing quality will be greater, thereby enabling manufacturing of a high-reliability product.

As set forth above, the SAW device package of the present invention has a beneficial effect of simplifying the manufacturing processes of a SAW device package. That is, compared with forming an airtight condition in the active area by the prior resin or metal dam structure in a surrounding form, the manufacturing processes of the present invention are lower in difficulty level and much simpler, and the conditions thereof are facilitated in the step of flip-bonding the bare chip to the wiring substrate.

Furthermore, compared with the prior art, the present invention provides a package with a stronger structure against the external environmental changes.

That is, in comparison with the prior SAW device package, the SAW device package of the present invention is structurally superior in that the wiring substrate is more elaborate having a stair-form interface, thereby further blocking moisture permeation from outside.

Overall, the SAW device package of the present invention is able to maintain protection of the active area while blocking the effects from the external environment, thereby enhancing the operational characteristics of the device, simplifying the manufacturing processes as well as saving the costs, and in turn, improving the overall product reliability.

While the present invention has been shown and described in connection with the preferred embodiments, it will be apparent to those skilled in the art that modifications and variations can be made without departing from the spirit and scope of the invention as defined by the appended claims.

1. A Surface Acoustic Wave (SAW) device package of improved sealing quality comprising:
a wiring substrate having bare chip attaching means, the wiring substrate being provided as a package base having connecting patterns;
the bare chip being attached to the bare chip attaching means and flip-bonded to the wiring substrate while maintaining the airtight condition of an active area; and
a resin molding part covering and sealing the bare chip and the wiring substrate,
wherein the bare chip attaching means comprises a first protrusion part that protrudes integrally in a surrounding form on the wiring substrate in order to tightly attach the rim of the bare chip that is flip-bonded to the wiring substrate,
wherein the wiring substrate comprises a second protrusion part that protrudes in a surrounding form on the rim of the first protrusion part, thereby allowing the resin molding part to seal the space between the bare chip and the second protrusion part.

2. The SAW device package according to claim 1, further comprising a plurality of bumps that are formed on input/output terminals of Inter-Digital Transducer (IDT) electrodes provided to the bare chip and flip-bonded to the connecting patterns of the wiring substrate.

3. (canceled)

4. (canceled)

5. The SAW device package according to claim 1, wherein the first protrusion part, which is the bare chip attaching means, protrudes from the surface having the connecting patterns thereon, in a height corresponding to the thickness of the bumps that are bonded to the wiring substrate,
the second protrusion part protrudes from the first protrusion part in a height at least the same as the thickness of the bare chip, and
the resin molding part is provided in a space formed between the second protrusion part and the peripheral sides of the bare chip.

6. The SAW device package according to claim 1, wherein the wiring substrate and the first protrusion part comprise a multi-layer ceramic structure integrally formed by tape-casting.

7. The SAW device package according to claim 1, wherein the wiring substrate, the first protrusion part and the second protrusion part comprise a multi-layer ceramic structure integrally formed by tape-casting.

8. The SAW device package according to claim 1, further comprising an adhesion layer formed on the first protrusion part to prevent resin permeation between the bare chip and the first protrusion part from the resin molding part into the active area of the attached bare chip.

9. The SAW device package according to claim 1, further comprising an adhesion layer formed on the first protrusion part to prevent resin permeation between the bare chip and the first protrusion part from the resin molding part into the active area of the attached bare chip.

10. The SAW device package according to claim 8, wherein the adhesion layer is made of metal of high ductility or rubber.

11. The SAW device package according to claim 9, wherein the adhesion layer is made of metal of high ductility or rubber.

12. The SAW device package according to claim 1, wherein the first protrusion part further comprises resin-receiving means for receiving resin flow therein before the active area in case of resin permeation from the resin molding part.

13. The SAW device package according to claim 1, wherein the first protrusion part further comprises resin-receiving means for receiving resin flow therein before the active area in case of resin permeation from the resin molding part.

14. The SAW device package according to claim 12, wherein the resin-receiving means comprises a resin inflow groove that is formed from the surface to the inside of the first protrusion part.

15. The SAW device package according to claim 13, wherein the resin-receiving means comprises a resin inflow groove that is formed from the surface to the inside of the first protrusion part.
